(19) United States
(12) Patent Application Publication
(10) Pub. No.: US 2022/0102420 A1
(43) Pub. Date: Mar. 31, 2022

(54) MANUFACTURING METHOD FOR SEMICONDUCTOR FILM, PHOTOELECTRIC CONVERSION ELEMENT, IMAGE SENSOR, AND SEMICONDUCTOR FILM

(71) Applicant: FUJIFILM Corporation, Tokyo (JP)

(72) Inventors: Masashi ONO, Kanagawa (JP); Masahiro TAKATA, Kanagawa (JP); Tetsushi MIYATA, Kanagawa (JP)

(73) Assignee: FUJIFILM Corporation, Tokyo (JP)

(21) Appl. No.: 17/545,991

(22) Filed: Dec. 8, 2021

Related U.S. Application Data
(63) Continuation of application No. PCT/JP2020/021607, filed on Jun. 1, 2020.

(30) Foreign Application Priority Data
Jul. 1, 2019 (JP) 2019-123104

(51) Int. Cl. H01L 27/146; C01G 21/21; C09K 11/02; C09K 11/66

(52) U.S. Cl. CPC H01L 27/14649; H01L 27/14621; B82Y 20/00; C09K 11/025; C09K 11/661; C01G 21/21

(57) ABSTRACT

A semiconductor film contains aggregates of semiconductor quantum dots containing a metal atom and a ligand that is coordinated to the semiconductor quantum dot, where the ligand contains a first ligand that is an inorganic halide and a second ligand that is represented by any one of Formulae (A) to (C). X^{A1} and X^{A2} are separated by L^{A1} by 1 or 2 atoms, X^{B1} and X^{B3}, and X^{B2} and X^{B3} are respectively independently separated by L^{B1} and L^{B2} by 1 or 2 atoms, and X^{C1} and X^{C4}, X^{C2} and X^{C4}, and X^{C3} and X^{C4} are respectively independently separated by L^{C1}, L^{C2}, or L^{C3} by 1 or 2 atoms.

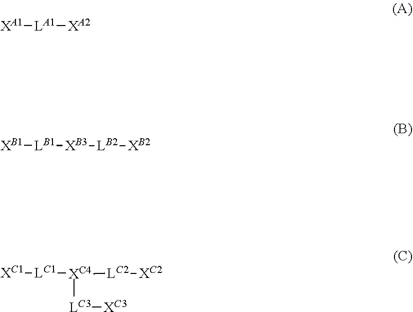

### CROSS-REFERENCE TO RELATED APPLICATIONS

This application is a Continuation of PCT International Application No. PCT/JP2020/021607 filed on Jun. 1, 2020, which claims priority under 35 U.S.C § 119(a) to Japanese Patent Application No. 2019-123104 filed on Jul. 1, 2019. Each of the above application(s) is hereby expressly incorporated by reference, in its entirety, into the present application.

### BACKGROUND OF THE INVENTION

### 1. Field of the Invention

The present invention relates to a semiconductor film containing semiconductor quantum dots that containing a metal atom, a photoelectric conversion element, an image sensor, and a method for manufacturing a semiconductor film.

### 2. Description of the Related Art

In recent years, attention has been focused on photodetector elements capable of detecting light in the infrared region in the fields such as smartphones, surveillance cameras, and in-vehicle cameras.

In the related art, a silicon photodiode in which a silicon wafer is used as a material of a photoelectric conversion layer has been used in a photodetector element that is used in an image sensor or the like. However, a silicon photodiode has low sensitivity in the infrared region having a wavelength of 900 nm or more.

In addition, an InGaAs-based semiconductor material known as a near-infrared light-receiving element has a problem in that it requires extremely high-cost processes such as epitaxial growth for achieving a high quantum efficiency, and thus it has not been widespread.

By the way, in recent years, research on semiconductor quantum dots has been advanced. A solar cell device, which has a semiconductor film containing PbS quantum dots treated with ZnI₂ and 3-mercaptopropionic acid as a photoelectric conversion layer, is disclosed in Santanu Pradhan, Alexandros Stavrinadis, Shuchi Gupta, Yu Bi, Francesco Di Stasio, and Gerasimos Konstantatos, “Trap-State Suppression and Improved Charge Transport in PbS Quantum Dot Solar Cells with Synergistic Mixed-Ligand Treatments”, Small 13, 1700598 (2017).

### SUMMARY OF THE INVENTION

As a result of studying the semiconductor film disclosed in Santanu Pradhan, Alexandros Stavrinadis, Shuchi Gupta, Yu Bi, Francesco Di Stasio, and Gerasimos Konstantatos, “Trap-State Suppression and Improved Charge Transport in PbS Quantum Dot Solar Cells with Synergistic Mixed-Ligand Treatments”, Small 13, 1700598 (2017), the inventors of the present invention found that in this semiconductor film, the in-plane variation of the external quantum efficiency is large. The inventors of the present invention also found that there is room for further improvement in electrical conductivity, photocurrent value, and external quantum efficiency.

An object of the present invention is to provide a semiconductor film that has a high electrical conductivity, a high photocurrent value, and a high external quantum efficiency and also has excellent in-plane uniformity of external quantum efficiency, a photoelectric conversion element, an image sensor, and a manufacturing method for a semiconductor film.

According to the study of the inventors of the present invention, it has been found that the above problems can be solved by adopting the following configurations, and the present invention has been completed. The present invention provides the following.

<1> A semiconductor film comprising:

aggregates of semiconductor quantum dots containing a metal atom; and

a ligand that is coordinated to the semiconductor quantum dot,

in which the ligand contains a first ligand that is an inorganic halide and a second ligand that is represented by any one of Formulae (A) to (C);

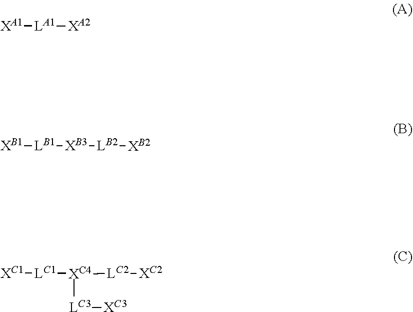

in Formula (A), X^{A1} and X^{A2} each independently represent a thiol group, an amino group, a hydroxy group, a carboxy group, a sulfo group, a phospho group, or a phosphonic acid group,

L^{A1} represents a hydrocarbon group, X^{A1} and X^{A2} are separated by L^{A1} by 1 or 2 atoms, and

in a case where one of X^{A1} and X^{A2} is a thiol group and the other is a carboxy group, X^{A1} and X^{A2} are separated by L^{A1} by 1 atom;

in Formula (B), X^{B1} and X^{B2} each independently represent a thiol group, an amino group, a hydroxy group, a carboxy group, a sulfo group, a phospho group, or a phosphonic acid group,

X^{B3} represents S, O, or NH,

L^{B1} and L^{B2} each independently represent a hydrocarbon group,

X^{B1} and X^{B3} are separated by L^{B1} by 1 or 2 atoms, and

X^{B2} and X^{B3} are separated by L^{B2} by 1 or 2 atoms; and

in Formula (C), X^{C1} to X^{C3} each independently represent a thiol group, an amino group, a hydroxy group, a carboxy group, a sulfo group, a phospho group, or a phosphonic acid group,

X^{C4} represents N,

L^{C1} to L^{C3} each independently represent a hydrocarbon group,

X^{C1} and X^{C4} are separated by L^{C1} by 1 or 2 atoms,

X² and X^{C4} are separated by L^{C2} by 1 or 2 atoms, and

X^{C3} and X^{C4} are separated by L^{C3} by 1 or 2 atoms.

<2> The semiconductor film according to <1>, in which the semiconductor quantum dot contains a Pb atom.

<3> The semiconductor film according to <1> or <2>, in which the first ligand contains at least one selected from a Group 12 element or a Group 13 element.

<4> The semiconductor film according to any one of <1> to <3>, in which the first ligand contains a Zn atom.

<5> The semiconductor film according to any one of <1> to <4>, in which the first ligand contains an iodine atom.

<6> The semiconductor film according to any one of <1> to <5>, in which the second ligand is at least one selected from thioglycolic acid, 2-aminoethanol, 2-aminoethanethiol, 2-mercaptoethanol, diethylenetriamine, tris(2-aminoethyl)amine, (aminomethyl)phosphonic acid, or derivatives thereof.

<7> The semiconductor film according to any one of <1> to <6>, in which the semiconductor film contains two or more kinds of the first ligand.

<8> The semiconductor film according to any one of <1> to <7>, in which the semiconductor film contains two or more kinds of the second ligand.

<9> The semiconductor film according to any one of <1> to <8>, in which the semiconductor film further contains a ligand other than the first ligand and the second ligand.

<10> A photoelectric conversion element comprising the semiconductor film according to any one of <1> to <9>.

<11> The photoelectric conversion element according to <10>, in which the photoelectric conversion element is a photodiode-type photodetector element.

<12> An image sensor comprising the photoelectric conversion element according to <10> or <11>.

<13> The image sensor according to <12>, in which the image sensor senses light having a wavelength of 900 nm to 1,600 nm.

<14> A manufacturing method for a semiconductor film, comprising:

a semiconductor quantum dot aggregate forming step of applying a semiconductor quantum dot dispersion liquid containing semiconductor quantum dots that contain a metal atom, a third ligand that is coordinated to a semiconductor quantum dot and that is different from a first ligand which is an inorganic halide and a second ligand which is represented by any of Formulae (A) to (C), and a solvent, onto a substrate to form a film of aggregates of the semiconductor quantum dots; and

a ligand exchange step of applying a ligand solution 1 containing the first ligand which is an inorganic halide and a solvent, and a ligand solution 2 containing the second ligand which is represented by any of Formulae (A) to (C), and a solvent, or applying a ligand solution 3 containing the first ligand which is an inorganic halide, the second ligand which is represented by any of Formulae (A) to (C), and a solvent, onto the film of the aggregates of the semiconductor quantum dots formed by the semiconductor quantum dot aggregate forming step, to exchange the third ligand coordinated to the semiconductor quantum dot with the first ligand and the second ligand;

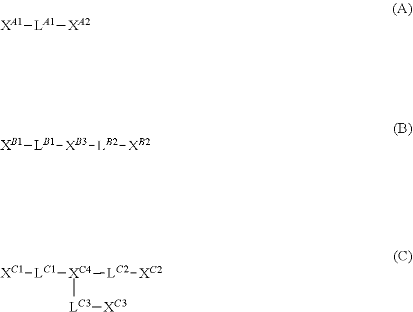

in Formula (A), X^{A1} and X^{A2} each independently represent a thiol group, an amino group, a hydroxy group, a carboxy group, a sulfo group, a phospho group, or a phosphonic acid group,

L^{A1} represents a hydrocarbon group, X^{A1} and X^{A2} are separated by L^{A1} by 1 or 2 atoms, and

in a case where one of X^{A1} and X^{A2} is a thiol group and the other is a carboxy group, X^{A1} and X^{A2} are separated by L^{A1} by 1 atom;

in Formula (B), X^{B1} and X^{B2} each independently represent a thiol group, an amino group, a hydroxy group, a carboxy group, a sulfo group, a phospho group, or a phosphonic acid group,

X^{B3} represents S, O, or NH,

L^{B1} and L^{B2} each independently represent a hydrocarbon group,

X^{B1} and X^{B3} are separated by L^{B1} by 1 or 2 atoms, and

X^{B2} and X^{B3} are separated by L^{B2} by 1 or 2 atoms; and

in Formula (C), X^{C1} to X^{C3} each independently represent a thiol group, an amino group, a hydroxy group, a carboxy group, a sulfo group, a phospho group, or a phosphonic acid group,

X^{C4} represents N,

L^{C1} to L^{C3} each independently represent a hydrocarbon group,

X^{C1} and X^{C4} are separated by L^{C1} by 1 or 2 atoms,

X² and X^{C4} are separated by L^{C2} by 1 or 2 atoms, and

X^{C3} and X^{C4} are separated by L^{C3} by 1 or 2 atoms.

<15> The manufacturing method for a semiconductor film according to <14>, further comprising a rinsing step of carrying out rinsing by bringing an aprotic solvent into contact with the film of the aggregates of the semiconductor quantum dots.

<16> The manufacturing method for a semiconductor film according to <15>, in which the aprotic solvent is an aprotic polar solvent.

<17> The manufacturing method for a semiconductor film according to <15>, in which the aprotic solvent is at least one selected from acetonitrile or acetone.

<18> The manufacturing method for a semiconductor film according to any one of <14> to <17>, in which in the semiconductor quantum dot aggregate forming step, a film of the aggregates of the semiconductor quantum dots having a thickness of 30 nm or more is formed, and

a complex stability constant K1 of the second ligand with respect to the metal atom contained in the semiconductor quantum dot is 6 or more.

<19> The manufacturing method for a semiconductor film according to <18>, in which the complex stability constant K1 of the second ligand with respect to the metal atom contained in the semiconductor quantum dot is 8 or more.

<20> The manufacturing method for a semiconductor film according to <18>, in which the semiconductor quantum dot contains a Pb atom, and

the complex stability constant K1 of the second ligand with respect to the Pb atom contained in the semiconductor quantum dot is 6 or more.

According to the present invention, it is possible to provide a semiconductor film that has a high electrical conductivity, a high photocurrent value, and a high external quantum efficiency and also has excellent in-plane uniformity of external quantum efficiency, a photoelectric conversion element, an image sensor, and a manufacturing method for a semiconductor film.

### BRIEF DESCRIPTION OF THE DRAWINGS

FIG. 1 is a diagram illustrating an embodiment of a photodetector element.

FIG. 2 is a diagram illustrating a substrate (a substrate having a comb-shaped platinum electrode) used for manufacturing a test specimen 1.

### DESCRIPTION OF THE PREFERRED EMBODIMENTS

Hereinafter, the contents of the present invention will be described in detail.

In the present specification, “to” is used to mean that numerical values described before and after “to” are included as a lower limit value and an upper limit value, respectively.

In describing a group (an atomic group) in the present specification, in a case where a description about substitution and non-substitution is not provided, the description means the group includes a group (an atomic group) having a substituent as well as a group (an atomic group) having no substituent. For example, the “alkyl group” includes not only an alkyl group that does not have a substituent (an unsubstituted alkyl group) but also an alkyl group that has a substituent (a substituted alkyl group).

<Semiconductor Film>

The semiconductor film according to the embodiment of the present invention is characterized the following:

the semiconductor film includes aggregates of semiconductor quantum dots containing a metal atom and

a ligand that is coordinated to the semiconductor quantum dot,

where the ligand contains a first ligand that is an inorganic halide and a second ligand that is represented by any one of Formulae (A) to (C).

The semiconductor film according to the embodiment of the present invention has a high electrical conductivity, a high photocurrent value, and a high external quantum efficiency and also has excellent in-plane uniformity of external quantum efficiency. The detailed reason why such effects are obtained is unknown; however, it is presumed to be due to the following. In the ligand represented by Formula (A) (hereinafter, also referred to as the ligand (A)) among the second ligands, it is presumed that the portions of X^{A1} and X^{A2} are coordinated to the metal atom of the semiconductor quantum dot. In addition, in the ligand represented by Formula (B) (hereinafter, also referred to as the ligand (B)), it is presumed that the portions of X^{B1} to X^{B3} are coordinated to the metal atom of the semiconductor quantum dot. In addition, in the ligand represented by Formula (C) (hereinafter, also referred to as the ligand (C)), it is presumed that the portions of X^{C1} to X^{C4} are coordinated to the metal atom of the semiconductor quantum dot. As described above, all of the ligand (A), the ligand (B), and the ligand (C) have a plurality of portions, in one molecule, which are coordinated to the metal atom of the semiconductor quantum dot, and thus it is presumed that they are subjected to chelate coordination to the metal atom of the semiconductor quantum dot. For this reason, it is conceived that the steric hindrance between the semiconductor quantum dots is reduced, and thus the semiconductor quantum dots are closely arranged to strengthen the overlap of the wave functions between the semiconductor quantum dots. In addition, according to the present invention, the first ligand which is an inorganic halide is further contained as the ligand that is coordinated to the semiconductor quantum dot, and thus it is presumed that the first ligand is coordinated in the gap where the second ligand is not coordinated, and it is presumed that the surface defects of the semiconductor quantum dot can be reduced. As a result, it is presumed that it has been possible to improve an electrical conductivity, a photocurrent value, an external quantum efficiency, an in-plane uniformity of external quantum efficiency.

Hereinafter, the details of the semiconductor film according to the embodiment of the present invention will be described.

(Aggregate of Semiconductor Quantum Dots Containing Metal Atom)

The semiconductor film has aggregates of semiconductor quantum dots containing a metal atom. The aggregate of semiconductor quantum dots means a form in which a large number of semiconductor quantum dots (for example, 100 or more quantum dots per 1 μm²) are arranged close to each other. In addition, the “semiconductor” in the present invention means a substance having a specific resistance value of 10⁻² Ω·cm or more and 10⁸ Ω·cm or less.

The semiconductor quantum dot is a semiconductor particle having a metal atom. It is noted that in the present invention, the metal atom also includes a metalloid atom represented by a Si atom. Examples of the semiconductor quantum dot material that constitutes the semiconductor quantum dot include a nano particle (a particle having a size of 0.5 nm or more and less than 100 nm) of a general semiconductor crystal [a) a Group IV semiconductor, b) a compound semiconductor of a Group IV to IV element, a Group III to V element, or a Group II to VI element, or c) a compound semiconductor consisting of a combination of three or more of a Group II element, a Group III element, a Group IV element, a Group V element, and a Group VI element].

The semiconductor quantum dot preferably contains at least one metal atom selected from a Pb atom, an In atom, a Ge atom, a Si atom, a Cd atom, a Zn atom, a Hg atom, an Al atom, a Sn atom, or a Ga atom, more preferably at least one metal atom selected from a Pb atom, an In atom, a Ge atom, or a Si atom, and due to the reason that the effects of the present invention are easily obtained more remarkably, it still more contains a Pb atom.

Specific examples of the semiconductor quantum dot material that constitutes the semiconductor quantum dot include semiconductor materials having a relatively narrow band gap, such as PbS, Pb Se, PbSeS, InN, InAs, Ge, InAs, InGaAs, CuInS, CuInSe, CuInGaSe, InSb, HgTe, HgCdTe, Ag₂S, Ag₂Se, Ag₂Te, SnS, SnSe, SnTe, Si, and InP. Among them, due to the reason that the absorption coefficient of light in the infrared region is large, the lifetime of photocurrent is long, the carrier mobility is large, and the like, the semiconductor quantum dot preferably contains PbS or PbSe and more preferably contains PbS.

The semiconductor quantum dot may be a material having a core-shell structure in which a semiconductor quantum dot material is made to the nucleus (the core) and the semiconductor quantum dot material is covered with a coating compound. Examples of the coating compound include ZnS, ZnSe, ZnTe, ZnCdS, CdS, and GaP.

The band gap of the semiconductor quantum dot is preferably 0.5 eV to 2.0 eV. In a case where the semiconductor film according to the embodiment of the present invention is applied to the use application to a photodetector element application, more specifically to a photoelectric conversion layer of a photodetector element, it can be made into a photodetector element capable of detecting light of various wavelengths depending on the use application. For example, it is possible to obtain a photodetector element capable of detecting light in the infrared region. The upper limit of the band gap of the semiconductor quantum dot is preferably 1.9 eV or less, more preferably 1.8 eV or less, and still more preferably 1.5 eV or less. The lower limit of the band gap of the semiconductor quantum dot is preferably 0.6 eV or more and more preferably 0.7 eV or more.

The average particle diameter of the semiconductor quantum dots is preferably 2 nm to 15 nm. The average particle diameter of the semiconductor quantum dots refers to the average particle diameter often semiconductor quantum dots. A transmission electron microscope may be used for measuring the particle diameter of the semiconductor quantum dots.

Generally, a semiconductor quantum dot contains particles of various sizes from several nm to several tens of nm. In the semiconductor quantum dot, in a case where the average particle diameter of semiconductor quantum dots is reduced to a size equal to or smaller than the Bohr radius of the internal electrons, a phenomenon in which the band gap of the semiconductor quantum dot changes due to the quantum size effect occurs. In a case where the average particle diameter of semiconductor quantum dots is 15 nm or less, it is easy to control the band gap by the quantum size effect.

The thickness of the semiconductor film is not particularly limited; however, it is preferably 10 nm to 600 nm, more preferably 50 nm to 600 nm, still more preferably 100 nm to 600 nm, and even still more preferably 150 nm to 600 nm, from the viewpoint of obtaining high electrical conductivity. The upper limit of the thickness is preferably 550 nm or less, more preferably 500 nm or less, and still more preferably 450 nm or less.

(Ligand)

The semiconductor film contains a ligand that is coordinated to the semiconductor quantum dot. The ligand contains a first ligand that is an inorganic halide and a second ligand that is represented by any one of Formulae (A) to (C). The semiconductor film may contain only one kind of the first ligand or may contain two or more kinds thereof. In addition, the semiconductor film may contain only one kind of the second ligand or may contain two or more kinds thereof.

[First Ligand]

First, the first ligand will be described. The first ligand is an inorganic halide. Examples of the halogen atom contained in the first ligand, that is, in the inorganic halide include a fluorine atom, a chlorine atom, a bromine atom, and an iodine atom, an iodine atom is preferable due to the reason that a high coordinating power is easily obtained.

The first ligand, that is, the inorganic halide preferably contains at least one selected from a Group 12 element or a Group 13 element. Among the above, the first ligand is preferably a compound containing a metal atom selected from a Zn atom, an In atom, and a Cd atom, and it is more preferably a compound containing a Zn atom. The inorganic halide is preferably a salt of a metal atom and a halogen atom due to the reason that the salt is easily ionized and easily coordinated to the semiconductor quantum dot.

Specific examples of the first ligand include zinc iodide, zinc bromide, zinc chloride, indium iodide, indium bromide, indium chloride, cadmium iodide, cadmium bromide, and cadmium chloride, gallium iodide, gallium bromide, and gallium chloride, and zinc iodide is particularly preferable.

Regarding the first ligand, the inorganic halide may be coordinated on the surface of the semiconductor quantum dot in the film, or it may be dissociated into a halogen ion and an inorganic ion, each of which may be coordinated on the surface of the semiconductor quantum dot. To describe with a specific example, in the case of zinc iodide, zinc iodide may be coordinated on the surface of the semiconductor quantum dot, or zinc iodide may be dissociated into an iodine ion and a zinc ion, each of which may be coordinated on the surface of the semiconductor quantum dot.

[Second Ligand]

Next, the second ligand will be described. The second ligand is a ligand represented by any one of Formulae (A) to (C). The second ligand is preferably a ligand represented by Formula (A) due to the reason that it is easy to increase the electrical conductivity, the photocurrent value, and the external quantum efficiency of the semiconductor film. The ligand represented by Formula (A) is a compound having a relatively low molecular weight and has a portion, at both ends, which is coordinated to the metal atom of the semiconductor quantum dot, and thus it is presumed that the ligand is easily subjected to chelate coordination to the metal atom of the semiconductor quantum dot, and furthermore, the steric hindrances between semiconductor quantum dots can be further reduced.

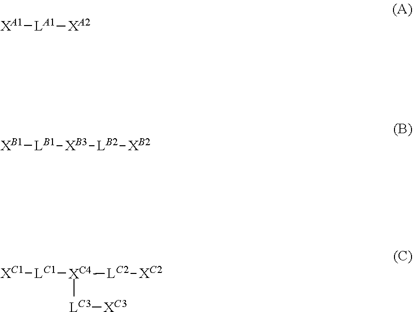

in Formula (A), X^{A1} and X^{A2} each independently represent a thiol group, an amino group, a hydroxy group, a carboxy group, a sulfo group, a phospho group, or a phosphonic acid group,

L^{A1} represents a hydrocarbon group, X^{A1} and X^{A2} are separated by L^{A1} by 1 or 2 atoms, and

in a case where one of X^{A1} and X^{A2} is a thiol group and the other is a carboxy group, X^{A1} and X^{A2} are separated L^{A1} by 1 atom;

in Formula (B), X^{B1} and X^{B2} each independently represent a thiol group, an amino group, a hydroxy group, a carboxy group, a sulfo group, a phospho group, or a phosphonic acid group,

X^{B3} represents S, O, or NH,

L^{B1} and L^{B2} each independently represent a hydrocarbon group,

X^{B1} and X^{B3} are separated by L^{B1} by 1 or 2 atoms, and

X^{B2} and X^{B3} are separated by L^{B2} by 1 or 2 atoms;

in Formula (C), X^{C1} to X^{C3} each independently represent a thiol group, an amino group, a hydroxy group, a carboxy group, a sulfo group, a phospho group, or a phosphonic acid group,

X^{C4} represents N,

L^{C1} to L^{C3} each independently represent a hydrocarbon group,

X^{C1} and X^{C4} are separated by L^{C1} by 1 or 2 atoms,

X² and X^{C4} are separated by L^{C2} by 1 or 2 atoms, and

X^{C3} and X^{C4} are separated by L^{C3} by 1 or 2 atoms.

The amino group represented by X^{A1}, X^{A2}, X^{B1}, X^{B2}, X^{C1}, X^{C2}, or X^{C3} is not limited to —NH₂ and includes a substituted amino group and a cyclic amino group as well. Examples of the substituted amino group include a monoalkylamino group, a dialkylamino group, a monoarylamino group, a diarylamino group, and an alkylarylamino group. The amino group represented by these groups is preferably —NH₂, a monoalkylamino group, or a dialkylamino group, and —NH₂ is more preferable.

In Formula (A), at least one of X^{A1} or X^{A2} is preferably a thiol group, an amino group, a hydroxy group, or a carboxy group, and more preferably a thiol group. Examples of the preferred combination of X^{A1} and X^{A2} include a combination in which one of X^{A1} and X^{A2} is a thiol group and the other is a thiol group, amino group, hydroxy group, or a carboxy group, and a combination in which one of X^{A1} and X^{A2} is an amino group and the other is a hydroxy group or a carboxy group. Among them, it is preferably a combination in which one of X^{A1} and X^{A2} is desirably a thiol group, and the other is a thiol group, an amino group, hydroxy group, or a carboxy group due to the reason that the coordinating power on the surface of the quantum dot is high and surface defects are easily reduced.

In Formula (A), it is also preferable that X^{A1} is a group different from X^{A2}. According to this aspect, the ligand is easily coordinated more firmly to the semiconductor quantum dot, and thus it is possible to further increase the electrical conductivity, the photocurrent value, the external quantum efficiency, and the in-plane uniformity of the external quantum efficiency. Furthermore, it is easy to suppress the occurrence of film peeling.

In Formula (B), at least one of X^{B1} or X^{B2} is preferably a thiol group, an amino group, or a hydroxy group, and more preferably an amino group. X^{B3} represents S, O, or NH, preferably O or NH, and more preferably NH.

In Formula (C), at least one of X^{C1} to X^{C3} is preferably a thiol group, an amino group, or a hydroxy group, and more preferably an amino group.

The hydrocarbon group represented by L^{A1}, L^{B1}, L^{B2}, L^{C1}, L^{C2}, or L^{C3} is preferably an aliphatic hydrocarbon group. The aliphatic hydrocarbon group may be a saturated aliphatic hydrocarbon group or may be an unsaturated aliphatic hydrocarbon group. The hydrocarbon group preferably has 1 to 6 carbon atoms, more preferably 1 to 3 carbon atoms, and particularly preferably 1 or 2 carbon atoms. Specific examples of the hydrocarbon group include an alkylene group, an alkenylene group, and an ethynylene group.

Examples of the alkylene group include a linear alkylene group, a branched alkylene group, and a cyclic alkylene group. A linear alkylene group or a branched alkylene group is preferable, and a linear alkylene group is more preferable. Examples of the alkenylene group include a linear alkenylene group, a branched alkenylene group, and a cyclic alkenylene group. A linear alkenylene group or a branched alkenylene group is preferable, and a linear alkenylene group is more preferable. The alkylene group and the alkenylene group may further have a substituent. The substituent is preferably a group having 1 or more and 10 or less atoms. Preferred specific examples of the group having 1 to 10 atoms include an alkyl group having 1 to 3 carbon atoms [a methyl group, an ethyl group, a propyl group, or an isopropyl group], an alkenyl group having 2 or 3 carbon atoms [an ethenyl group or a propenyl group], an alkynyl group having 2 to 4 carbon atoms [an ethynyl group, a propynyl group, or the like], a cyclopropyl group, an alkoxy group having 1 or 2 carbon atoms [a methoxy group or an ethoxy group], an acyl group having 2 or 3 carbon atoms [an acetyl group or a propionyl group], an alkoxycarbonyl group having 2 or 3 carbon atoms [a methoxycarbonyl group or an ethoxycarbonyl group], an acyloxy group having 2 carbon atoms [an acetyloxy group], an acylamino group having 2 carbon atoms [an acetylamino group], a hydroxyalkyl group having 1 to 3 carbon atoms [a hydroxymethyl group, a hydroxyethyl group, or a hydroxypropyl group], an aldehyde group, a hydroxy group, a carboxy group, a sulfo group, a phospho group, a carbamoyl group, a cyano group, an isocyanate group, a thiol group, a nitro group, a nitroxy group, an isothiocyanate group, a cyanate group, a thiocyanate group, an acetoxy group, an acetamide group, a formyl group, a formyloxy group, a formamide group, a sulfamino group, a sulfino group, a sulfamoyl group, a phosphono group, an acetyl group, a halogen atom, and an alkali metal atom.

In Formula (A), X^{A1} and X^{A2} are separated by L^{A1} by one or two atoms, and in a case where one of X^{A1} and X^{A2} is a thiol group and the other is carboxy group,

X^{A1} and X^{A2} are separated L^{A1} by one atom.

In Formula (B), X^{B1} and X^{B3} are separated by L^{B1} by one or two atoms, and X^{B2} and X^{B3} are separated by L^{B2} by one or two atoms.

In Formula (C), X^{C1} and X^{C4} are separated by L^{C1} by one or two atoms, X^{C2} and X^{C4} are separated by L^{C2} by one or two atoms, and X^{C3} and X^{C4} are separated by L^{C3} by one or two atoms.

It is noted that the description that X^{A1} and X^{A2} are separated by L^{A1} by 1 or 2 atoms means that the number of atoms that constitute the shortest molecular chain connecting X^{A1} and X^{A2} is 1 or 2 atoms. For example, in any one of Formulae (A1) to (A3), X^{A1} and X^{A2} are separated by two atoms. The numbers added to the following structural formulae represent the arrangement order of atoms constituting the shortest distance molecular chain connecting X^{A1} and X^{A2}.

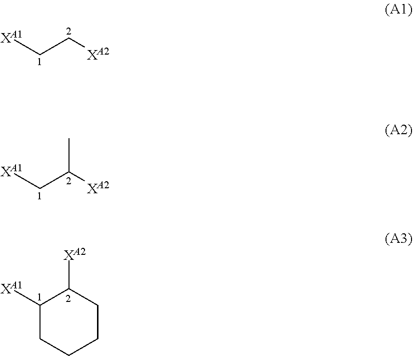

To describe with a specific compound, thioglycolic acid is a compound (a compound having the following structure) having a structure in which a portion corresponding to X^{A1} is a thiol group, a portion corresponding to X^{A2} is a carboxy group, and a portion corresponding to L^{A1} is sylene group. In thioglycolic acid, X^{A1} (the thiol group) and X^{A2} (the carboxy group) are separated by L^{A1} (the methylene group) by one atom.

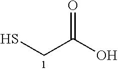

The same applies to the meanings that X^{B1} and X^{B3} are separated by L^{B1} by 1 or 2 atoms, X^{B2} and X^{B3} are separated by L^{B2} by 1 or 2 atoms, X^{C1} and X^{C4} are separated by L^{C1} by 1 or 2 atoms, X^{C2} and X^{C4} are separated by L^{C2} by 1 or 2 atoms, and X^{C3} and X^{C4} are separated by L^{C3} by 1 or 2 atoms.

Specific examples of the second ligand include thioglycolic acid, 2-aminoethanol, 2-aminoethanethiol, 2-mercaptoethanol, glycolic acid, diethylenetriamine, tris(2-aminoethyl)amine, 1-thioglycerol, dimercaprol, ethylenediamine, ethyleneglycol, aminosulfonic acid, glycine, (aminomethyl)phosphonic acid, guanidine, diethanolamine, 2-(2-aminoethyl)aminoethanol, homoserine, cysteine, thiomalic acid, malic acid, tartaric acid, and derivatives thereof. Among them, thioglycolic acid, 2-aminoethanol, 2-mercaptoethanol, or 2-aminoethanethiol is preferable, and thioglycolic acid is more preferable, due to the reason that the effects of the present invention are obtained more remarkably.

The complex stability constant K1 of the second ligand with respect to the metal atom contained in the semiconductor quantum dot is preferably 6 or more, more preferably 8 or more, and still more preferably 9 or more. In a case where the complex stability constant K1 is 6 or more, the strength of the bond between the semiconductor quantum dot and the second ligand can be increased. As a result, it is possible to suppress the peeling of the second ligand or the like from the semiconductor quantum dot, and as a result, it is possible to further improve the electrical conductivity, the photocurrent value, the external quantum efficiency, the in-plane uniformity of external quantum efficiency, and the like.

The complex stability constant K1 is a constant determined by the relationship between a ligand and a metal atom which is a target of the coordinate bond, and it is represented by Expression (b).

Complex stability constant K1=[ML]/([M]×[L]) (b)

In Expression (b), [ML] represents the molar concentration of a complex formed by bonding a metal atom to a ligand, [M] represents the molar concentration of a metal atom contributing to the coordinate bond, and [L] represents the molar concentration of the ligand.

Practically, a plurality of ligands may be coordinated to one metal atom. However, in the present invention, the complex stability constant K1 represented by Expression (b) in a case where one ligand molecule is coordinated to one metal atom is defined as an indicator of the strength of the coordinate bond.

The complex stability constant K1 between the ligand and the metal atom can be determined by spectroscopy, magnetic resonance spectroscopy, potentiometry, solubility measurement, chromatography, calorimetry, solidifying point measurement, vapor pressure measurement, relaxation measurement, viscosity measurement, surface tension measurement, or the like. In the present invention, the complex stability constant K1 is determined using Sc-Database ver. 5.85 (Academic Software) (2010), which summarizes results from various methods and research institutes. In a case where the complex stability constant K1 is not present in the Sc-Database ver. 5.85, a value described in Critical Stability Constants, written by A. E. Martell and R. M. M. Smith, is used. In a case where the complex stability constant K1 is not described in the Critical Stability Constants, the above-described measurement method is used or a program PKAS method that calculates the complex stability constant K1 (The Determination and Use of Stability Constants, VCH (1988) written by A. E. Martell et. al.) is used to calculate the complex stability constant K1.

In the present invention, a quantum dot containing a Pb atom (more preferably, PbS is used) is used as the semiconductor quantum dot, the complex stability constant K1 of the second ligand with respect to the Pb atom is preferably 6 or more, more preferably 8 or more, and still more preferably 9 or more. Examples of the compound having a complex stability constant K1 of 6 or more with respect to the Pb atom include thioglycolic acid (complex stability constant K1 with respect to Pb=8.5), 2-mercaptoethanol (complex stability constant K1 with respect to Pb=6.7), aminoethanol (complex stability constant K1 with respect to Pb=8.4), and 2-aminoethanethiol (complex stability constant K1 with respect to Pb=10.1).

[Another Ligand]

The semiconductor film may further contain a ligand other than the first ligand and the second ligand (hereinafter, also referred to as another ligand) as the ligand that is coordinated to the semiconductor quantum dot. Examples of the other ligand include a ligand represented by any of Formulae (D) to (F) and 3-mercaptopropionic acid.

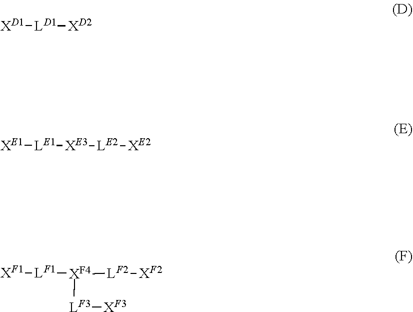

In Formula (D), X^{D1} and X^{D2} each independently represent a thiol group, an amino group, a hydroxy group, a carboxy group, a sulfo group, a phospho group, or a phosphonic acid group, and

L^{D1} represents a hydrocarbon group, and X^{D1} and X^{D2} are separated by L^{D1} by 3 to 10 atoms;

in Formula (E), X^{E1} and X^{E2} each independently represent a thiol group, an amino group, a hydroxy group, a carboxy group, a sulfo group, a phospho group, or a phosphonic acid group,

X^{E3} represents S, O, or NH,

L^{E1} and L^{E2} each independently represent a hydrocarbon group,

X^{E1} and X^{E3} are separated by L^{E1} by 3 to 10 atoms, and

X^{E2} and X^{E3} are separated by L^{E2} by 1 to 10 atoms;

in Formula (F), X^{F1} to X^{F3} each independently represent a thiol group, an amino group, a hydroxy group, a carboxy group, a sulfo group, a phospho group, or a phosphonic acid group,

X^{F4} represents N,

L^{F1} to L^{F3} each independently represent a hydrocarbon group,

X^{F1} and X^{F4} are separated by L^{F1} by 3 to 10 atoms,

X^{F2} and X^{F4} are separated by L^{F2} by 1 to 10 atoms, and

X^{F3} and X^{F4} are separated by L^{F3} by 1 to 10 atoms.

In a case where the semiconductor film contains the other ligand as a ligand that is coordinated to the semiconductor quantum dot, the second ligand is preferably 50% by mass or more, more preferably 70% by mass or more, still more preferably 80% by mass or more, and particularly preferably 90% by mass or more, with respect to the total mass of the second ligand and the other ligand. In addition, none of the ligand represented by Formula (D), the ligand represented by Formula (E), and the ligand represented by Formula (F) may be contained.

<Manufacturing Method for Semiconductor Film>

The manufacturing method for a semiconductor film according to the embodiment of the present invention includes;

a semiconductor quantum dot aggregate forming step of applying a semiconductor quantum dot dispersion liquid containing semiconductor quantum dot that contains a metal atom, a third ligand that is coordinated to a semiconductor quantum dot and that is different from a first ligand which is an inorganic halide and a second ligand which is represented by any of Formulae (A) to (C), and a solvent, onto a substrate to form a film of aggregates of the semiconductor quantum dots, and

a ligand exchange step of applying a ligand solution 1 containing the first ligand which is an inorganic halide and a solvent, and a ligand solution 2 containing the second ligand which is represented by any of Formulae (A) to (C), and a solvent, or applying a ligand solution 3 containing the first ligand which is an inorganic halide, the second ligand which is represented by any of Formulae (A) to (C), and a solvent, onto the film of the aggregates of the semiconductor quantum dots formed by the semiconductor quantum dot aggregate forming step, to exchange the third ligand coordinated to the semiconductor quantum dot with the first ligand and the second ligand.

In the manufacturing method for a semiconductor film according to the embodiment of the present invention, the semiconductor quantum dot aggregate forming step and the ligand exchange step may be alternately repeated a plurality of times. In addition, a rinsing step of bringing a rinsing liquid into contact with the film of aggregates of semiconductor quantum dots to rinse the film may be further included.

In the manufacturing method for a semiconductor film according to the embodiment of the present invention, in the semiconductor quantum dot aggregate forming step, a semiconductor quantum dot dispersion liquid is applied onto a substrate to form a film of aggregates of semiconductor quantum dots on the substrate. At this time, since the semiconductor quantum dots are dispersed in the solvent by the third ligand, the semiconductor quantum dots hardly become an aggregated bulky shape. As a result, in a case where the semiconductor quantum dot dispersion liquid is applied onto a substrate, it is possible to make the aggregates of semiconductor quantum dots have a configuration in which each semiconductor quantum dot is arranged.

Next, by the ligand exchange step, the ligand solution 1 containing the first ligand and a solvent and the ligand solution 2 containing the second ligand and a solvent are applied onto the film of aggregates of semiconductor quantum dots, or the ligand solution 3 containing the first ligand, the second ligand, and a solvent is applied onto the film thereof, whereby the ligand exchange occurs between the third ligand coordinated to the semiconductor quantum dot, and the first ligand and the second ligand. For this reason, it is conceived that the semiconductor quantum dots are easily brought close with each other. Since the semiconductor quantum dots are brought close with each other, the electrical conductivity of the aggregate of the semiconductor quantum dots is increased, and a semiconductor film having a high photocurrent value and a high external quantum efficiency can be obtained.

Each step will be described in more detail below.

(Semiconductor Quantum Dot Aggregate Forming Step)

In the semiconductor quantum dot aggregate forming step, a semiconductor quantum dot dispersion liquid, which contains the semiconductor quantum dots containing a metal atom, the third ligand coordinated to the semiconductor quantum dot, and a solvent, is applied onto a substrate to form a film of aggregates of semiconductor quantum dots.

The semiconductor quantum dot dispersion liquid may be applied onto the surface of the substrate or may be applied onto another layer provided on the substrate. Examples of the other layer provided on the substrate include an adhesive layer for improving the adhesion between the substrate and the aggregate of semiconductor quantum dots, and a transparent conductive layer.

The semiconductor quantum dot dispersion liquid contains the semiconductor quantum dots having a metal atom, the third ligand, and a solvent. The semiconductor quantum dot dispersion liquid may further contain other components as long as the effects of the present invention are not impaired.

The details of the semiconductor quantum dot containing a metal atom, contained in the semiconductor quantum dot dispersion liquid, are as described above, and the preferred aspect thereof is also the same as described above. The content of the semiconductor quantum dot in the semiconductor quantum dot dispersion liquid is preferably 1 mg/mL to 500 mg/mL, more preferably 10 mg/mL to 200 mg/mL, and still more preferably 20 mg/mL to 100 mg/mL. In a case where the content of the semiconductor quantum dot in the semiconductor quantum dot dispersion liquid is 1 mg/mL or more, the density of the semiconductor quantum dot on the substrate becomes high, and thus a good film is easily obtained. On the other hand, in a case where the content of the semiconductor quantum dot is 500 mg/mL or less, the film thickness of the film obtained by applying the semiconductor quantum dot dispersion liquid once is hardly increased. As a result, in the following ligand exchange step, it is possible to sufficiently carry out the ligand exchange of the third ligand coordinated to the semiconductor quantum dot present in the film.

The third ligand contained in the semiconductor quantum dot dispersion liquid acts as a ligand that is coordinated to the semiconductor quantum dot and has a molecular structure that easily causes steric hindrance, and thus it is preferable that the dispersion liquid also serves as a dispersing agent that disperses semiconductor quantum dots in the solvent.

From the viewpoint of improving the dispersibility of semiconductor quantum dots, the third ligand is preferably a ligand having at least 6 or more carbon atoms in the main chain and is more preferably a ligand having 10 or more carbon atoms in the main chain. The third ligand may be any one of a saturated compound or an unsaturated compound. Specific examples of the third ligand include decanoic acid, lauric acid, myristic acid, palmitic acid, stearic acid, behenic acid, oleic acid, erucic acid, oleyl amine, dodecyl amine, dodecanethiol, 1,2-hexadecanethiol, trioctylphosphine oxide, and cetrimonium bromide. The third ligand is preferably one that hardly remains in the film after the formation of the semiconductor film. Specifically, it is preferable that the molecular weight thereof is small. The third ligand is preferably oleic acid or oleyl amine from the viewpoint of imparting the dispersion stability to the semiconductor quantum dots and hardly remaining on the semiconductor film.

The content of the third ligand in the semiconductor quantum dot dispersion liquid is preferably 0.1 mmol/L to 500 mmol/L and more preferably 0.5 mmol/L to 100 mmol/L with respect to the total volume of the semiconductor quantum dot dispersion liquid.

The solvent contained in the semiconductor quantum dot dispersion liquid is not particularly limited; however, it is preferably a solvent that is difficult to dissolve the semiconductor quantum dots and easily dissolves the third ligand. The solvent is preferably an organic solvent. Specific examples thereof include an alkane [n-hexane, n-octane, or the like], benzene, and toluene. The solvent contained in the semiconductor quantum dot dispersion liquid may be only one kind or may be a mixed solvent in which two or more kinds are mixed.

The solvent contained in the semiconductor quantum dot dispersion liquid is preferably a solvent that does not easily remain in the formed semiconductor film. In a case where the solvent has a relatively low boiling point, the content of the residual organic substance can be suppressed when the semiconductor film has finally been obtained. In addition, the solvent is preferably a solvent having good wettability to the substrate. For example, in a case where the semiconductor quantum dot dispersion liquid is applied onto a glass substrate, the solvent is preferably an alkane such as hexane or octane.

The content of the solvent in the semiconductor quantum dot dispersion liquid is preferably 50% by mass to 99% by mass, more preferably 70% by mass to 99% by mass, and still more preferably 90% by mass to 98% by mass, with respect to the total mass of the semiconductor quantum dot dispersion liquid

The semiconductor quantum dot dispersion liquid is applied onto a substrate. The shape, structure, size, and the like of the substrate are not particularly limited, and the substrate can be appropriately selected depending on the intended purpose. The structure of the substrate may be a monolayer structure or a laminated structure. As the substrate, for example, a substrate composed of an inorganic material such as glass or yttria-stabilized zirconia (YSZ), a resin, a resin composite material, or the like can be used. In addition, an electrode, an insulating film, or the like may be formed on the substrate. In that case, the semiconductor quantum dot dispersion liquid is applied onto the electrode or the insulating film on the substrate.

The method for applying a semiconductor quantum dot dispersion liquid onto a substrate is not particularly limited. Examples thereof include coating methods such as a spin coating method, a dipping method, an inkjet method, a dispenser method, a screen printing method, a relief printing method, an intaglio printing method, and a spray coating method.

The thickness of the film of aggregates of the semiconductor quantum dots, formed by the semiconductor quantum dot aggregate forming step, is preferably 3 nm or more, more preferably 10 nm or more, and still more preferably 30 nm or more. The upper limit thereof is preferably 200 nm or less, more preferably 150 nm or less, and still more preferably 100 nm or less.

(Ligand Exchange Step)

In the ligand exchange step, the ligand solution 1 containing the first ligand and a solvent as well as the ligand solution 2 containing the second ligand and a solvent is applied onto the film of aggregates of semiconductor quantum dots, which are formed by the semiconductor quantum dot aggregate forming step, or the ligand solution 3 containing the first ligand, the second ligand, and a solvent is applied onto the film thereof, whereby the third ligand coordinated to the semiconductor quantum dot is exchanged with the first ligand and the second ligand.

Details of the first ligand contained in the ligand solution 1 and the ligand solution 3 as well as the second ligand contained in the ligand solution 2 and the ligand solution 3 are as described above, and the preferred aspects thereof are the same as described above.

In addition, the complex stability constant K1 of the second ligand with respect to the metal atom contained in the semiconductor quantum dot is preferably 6 or more, more preferably 8 or more, and still more preferably 9 or more. In a case where the complex stability constant K1 is 6 or more, it is possible to rapidly carry out the ligand exchange between the third ligand and the second ligand, and it is possible to sufficiently carry out ligand exchange up to the bottom part side of the film even in a case where the film thickness of the film of aggregates of the semiconductor quantum dots formed by the semiconductor quantum dot aggregate forming step is large. As a result, it is possible to carry out ligand exchange up to the bottom part of the film even in a case where the film thickness formed per cycle is large, and thus it is possible to shorten the tact time in manufacturing a semiconductor film having a desired film thickness, although the semiconductor quantum dot aggregate forming step and the ligand exchange step are generally repeated alternately a plurality of times to form a semiconductor film having a desired film thickness. In addition, in a case where the complex stability constant K1 is 6 or more, it is possible to firmly coordinate the second ligand to the semiconductor quantum dot, and thus it is possible to further improve, for example, the electrical conductivity, the photocurrent value, the external quantum efficiency, the in-plane uniformity of external quantum efficiency of the semiconductor film.

In the semiconductor quantum dot aggregate forming step, in a case where a film of aggregates of semiconductor quantum dots, having a thickness of 30 nm or more is formed, the complex stability constant K1 of the second ligand with respect to the metal atom contained in the semiconductor quantum dot is preferably 6 or more, more preferably 8 or more, and still more preferably 9 or more. In addition, in a case where a quantum dot containing a Pb atom (more preferably, PbS is used) is used as the semiconductor quantum dot, the complex stability constant K1 of the second ligand with respect to the Pb atom is preferably 6 or more, more preferably 8 or more, and still more preferably 9 or more.

The content of the first ligand contained in the ligand solution 1 and the ligand solution 3 is preferably 1 mmol/L to 500 mmol/L, more preferably 5 mmol/L to 100 mmol/L, and still more preferably 10 mmol/L to 50 mmol/L.

The content of the second ligand contained in the ligand solution 2 and the ligand solution 3 is preferably 0.001 v/v % to 5 v/v %, more preferably 0.002 v/v % to 1 v/v %, and still more preferably 0.005 v/v % to 0.1 v/v %.

The solvent contained in the ligand solution 1, the ligand solution 2, and the ligand solution 3 is preferably selected appropriately according to the kind of the ligand contained in each ligand solution, and it is preferably a solvent that easily dissolves each ligand. In addition, the solvent contained in the ligand solution is preferably an organic solvent having a high dielectric constant. Specific examples thereof include ethanol, acetone, methanol, acetonitrile, dimethylformamide, dimethyl sulfoxide, butanol, and propanol.

In addition, the solvent contained in the ligand solution is preferably a solvent that does not easily remain in the formed semiconductor film. From the viewpoints of easy drying and easy removal by washing, a low boiling point alcohol, a ketone, or a nitrile is preferable, and methanol, ethanol, acetone, or acetonitrile is more preferable. The solvent contained in the ligand solution is preferably one that does not mix with the solvent contained in the semiconductor quantum dot dispersion liquid. Regarding the preferred solvent combination, in a case where the solvent contained in the semiconductor quantum dot dispersion liquid is an alkane such as hexane or octane, it is preferable to use a polar solvent such as methanol or acetone as the solvent contained in the ligand solution.

The content of the solvent in the ligand solution is the remainder obtained by subtracting the content of the ligand from the total mass of the ligand solution.

The method for applying the ligand solution onto the aggregate of semiconductor quantum dots is the same as the method for applying the semiconductor quantum dot dispersion liquid onto the substrate, and the preferred aspect is also the same as described above.

(Rinsing Step)

The manufacturing method for a semiconductor film of the present invention may include a rinsing step in which a rinsing liquid is brought into contact with a film of aggregates of semiconductor quantum dots to rinse the film. In a case where the rinsing step is included, it is possible to remove the excess ligand contained in the film and the ligand eliminated from the semiconductor quantum dots. In addition, it is possible to remove the remaining solvent and other impurities. As the rinsing liquid, the solvent contained in the semiconductor quantum dot dispersion liquid or the ligand solution can be used; however, it is preferably an aprotic solvent and more preferably an aprotic polar solvent due to the reason that it is easy to more effectively remove the excess ligand contained in the film or the ligand eliminated from the semiconductor quantum dot, and it is easy to keep the film surface shape uniform by rearranging the surface of the quantum dots. The boiling point of the rinsing liquid is preferably 120° C. or lower, more preferably 100° C. or lower, and still more preferably 90° C. or lower, due to the reason that it is easy to remove the rinsing liquid after the film is formed. The boiling point of the rinsing liquid is preferably 30° C. or higher, more preferably 40° C. or higher, and still more preferably 50° C. or higher, due to the reason that it is possible to avoid unnecessary concentration during the operation. From the above, the boiling point of the rinsing liquid is preferably 50° C. to 90° C. Specific examples of the aprotic solvent include acetonitrile, acetone, dimethylformamide, and dimethyl sulfoxide, and acetonitrile or acetone is preferable due to the reason that it has a low boiling point and hardly remains in the film.

In the rinsing step, the rinsing liquid may be poured onto the film of aggregates of the semiconductor quantum dots, or the film of aggregates of the semiconductor quantum dots may be immersed in the rinsing liquid. In addition, the rinsing step may be carried out after the semiconductor quantum dot aggregate forming step or after the ligand exchange step. In addition, it may be carried out after repeating the set of the semiconductor quantum dot aggregate forming step and the ligand exchange step.

It is preferable that metal impurities of the solvent that is used in the semiconductor quantum dot aggregate forming step, the ligand exchange step, and the rinsing step is small, and the metal content is, for example, 10 ppb (parts per billion) by mass or less. A solvent of a level of ppt (parts per trillion) by mass may be used as necessary, and such a solvent is provided by, for example, TOAGOSEI Co., Ltd. (The Chemical Daily, Nov. 13, 2015). Examples of the method for removing impurities such as metals from the solvent include distillation (molecular distillation, thin film distillation, and the like) and filtration using a filter. The filter pore diameter of the filter that is used for filtration is preferably 10 μm or less, more preferably 5 μm or less, and still more preferably 3 μm or less. A material of the filter is preferably polytetrafluoroethylene, polyethylene, or nylon. In addition, the solvent may contain isomers (compounds having the same number of atoms but having different structures), and only one type of isomer may be contained or a plurality of types of isomers may be contained.

(Drying Step)

The manufacturing method for a semiconductor film according to the embodiment of the present invention may include a drying step. The drying step may be a dispersion liquid drying step of drying and removing the solvent remaining in the film of aggregates of the semiconductor quantum dots after the semiconductor quantum dot aggregate forming step or a solution drying step of drying the ligand solution after the ligand exchange step. In addition, it may be an integral step that is carried out after repeating the set of the semiconductor quantum dot aggregate forming step and the ligand exchange step.

A semiconductor film is formed on the substrate by undergoing each of the steps described above. The obtained semiconductor film of the present invention has a high electrical conductivity, a high photocurrent value, and a high external quantum efficiency and also has excellent in-plane uniformity of external quantum efficiency.

<Photoelectric Conversion Element>

The photoelectric conversion element according to the embodiment of the present invention includes the above-described semiconductor film according to the embodiment of the present invention. More preferably, the semiconductor film according to the embodiment of the present invention is included as the photoelectric conversion layer.

The thickness of the semiconductor film according to the embodiment of the present invention in the photoelectric conversion element is preferably 10 nm to 600 nm, more preferably 50 nm to 600 nm, still more preferably 100 nm to 600 nm, and even still more preferably 150 nm to 600 nm. The upper limit of the thickness is preferably 550 nm or less, more preferably 500 nm or less, and still more preferably 450 nm or less.

Examples of the kind of photoelectric conversion element include a photodetector element such as a sensor and a photovoltaic element such as a solar cell. Since the semiconductor film according to the embodiment of the present invention is excellent in the in-plane uniformity of external quantum efficiency, it is particularly effective in a case of being used as a photodetector element. That is, in a case where the external quantum efficiency widely varies in the plane in the photodetector element, which causes noise, the quality of the acquired image in a case of an image sensor as an example may deteriorate, and thus the function as the sensor functions easily decreases. For this reason, the photodetector element is required to have high in-plane uniformity of external quantum efficiency. Examples of the type of photodetector element include a photoconductor-type photodetector element and a photodiode-type photodetector element. Among the above, a photodiode-type photodetector element is preferable due to the reason that a high signal-to-noise ratio (SN ratio) is easily obtained.

In addition, since the semiconductor film according to the embodiment of the present invention has excellent sensitivity to the light having a wavelength in the infrared region, the photoelectric conversion element according to the embodiment of the present invention is preferably used as a photodetector element that detects light having a wavelength in the infrared region. That is, the photoelectric conversion element according to the embodiment of the present invention is preferably used as an infrared photodetector element.

The light having a wavelength in the infrared region is preferably light having a wavelength of more than 700 nm, more preferably light having a wavelength of 800 nm or more, and still more preferably light having a wavelength of 900 nm or more. In addition, the light having a wavelength in the infrared region is preferably light having a wavelength of 2,000 nm or less and more preferably light having a wavelength of 1,600 nm or less.

The photoelectric conversion element may be a photodetector element that simultaneously detects light having a wavelength in the infrared region and light having a wavelength in the visible region (preferably light having a wavelength in a range of 400 to 700 nm).

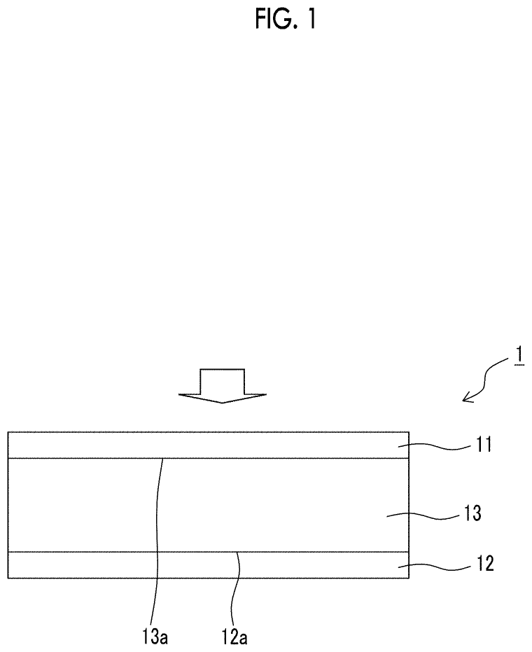

FIG. 1 illustrates an embodiment of a photodiode-type photodetector element. It is noted that an arrow in the figure represents the incidence ray on the photodetector element. A photodetector element 1 illustrated in FIG. 1 includes a lower electrode 12, an upper electrode 11 opposite to the lower electrode 12, and a photoelectric conversion layer 13 provided between the lower electrode 12 and the upper electrode 11. The photodetector element 1 illustrated in FIG. 1 is used by causing light to be incident from above the upper electrode 11.

The photoelectric conversion layer 13 is composed of the above-described semiconductor film according to the embodiment of the present invention.

The refractive index of the photoelectric conversion layer 13 with respect to the light of the target wavelength to be detected by the photodetector element is preferably 2.0 to 3.0, more preferably 2.1 to 2.8, and still more preferably 2.2 to 2.7. According to this aspect, in a case where the configuration of the photodetector element is a photodiode, it is easy to realize a high light absorbance, that is, a high external quantum efficiency.

The thickness of the photoelectric conversion layer 13 is preferably 10 nm to 600 nm, more preferably 50 nm to 600 nm, still more preferably 100 nm to 600 nm, and even still more preferably 150 nm to 600 nm. The upper limit of the thickness is preferably 550 nm or less, more preferably 500 nm or less, and still more preferably 450 nm or less.

The wavelength λ of the target light to be detected by the photodetector element and an optical path length L^{λ} of the light having the wavelength λ from a surface 12a of the lower electrode 12 on a side of the photoelectric conversion layer 13 to a surface 13a of the photoelectric conversion layer 13 on a side of the upper electrode preferably satisfy the relationship of Expression (1-1), and more preferably satisfy the relationship of Expression (1-2). In a case where the wavelength λ and the optical path length L^{λ} satisfy such a relationship, in the photoelectric conversion layer 13, it is possible to arrange a phase of the light (the incidence ray) incident from the side of the upper electrode 11 and a phase of the light (the reflected light) reflected on the surface of the lower electrode 12, and as a result, the light is intensified by the optical interference effect, whereby it is possible to obtain a higher external quantum efficiency.

0.05+m/2≤L^{λ}/λ≤0.35+m/2 (1-1)

0.10+m/2≤L^{λ}/λ≤0.30+m/2 (1-2)

In the above expressions, λ is the wavelength of the target light to be detected by the photodetector element,

L^{λ} is the optical path length of light having a wavelength λ from a surface 12a of the lower electrode 12 on a side of the photoelectric conversion layer 13 to a surface 13a of the photoelectric conversion layer 13 on a side of the upper electrode, and

m is an integer of 0 or more.

m is preferably an integer of 0 to 4, more preferably an integer of 0 to 3, still more preferably an integer of 0 to 2, and particularly preferably 0 or 1.

Here, the optical path length means the product obtained by multiplying the physical thickness of a substance through which light transmits by the refractive index. To describe with the photoelectric conversion layer 13 as an example, in a case where the thickness of the photoelectric conversion layer is denoted by d¹ and the refractive index of the photoelectric conversion layer with respect to the wavelength λ¹ is denoted by N¹, the optical path length of the light having a wavelength λ¹ and transmitting through the photoelectric conversion layer 13 is N¹×d¹. In a case where the photoelectric conversion layer 13 is composed of two or more laminated films or in a case where an interlayer described later is present between the photoelectric conversion layer 13 and the lower electrode 12, the integrated value of the optical path length of each layer is the optical path length

The upper electrode 11 is preferably a transparent electrode formed of a conductive material that is substantially transparent with respect to the wavelength of the target light to be detected by the photodetector element. It is noted that in the present invention, the description of “substantially transparent” means that the light transmittance is 50% or more, preferably 60% or more, and particularly preferably 80% or more. Examples of the material of the upper electrode 11 include a conductive metal oxide. Specific examples thereof include tin oxide, zinc oxide, indium oxide, indium tungsten oxide, indium zinc oxide (IZO), indium tin oxide (ITO), and a fluorine-doped tin oxide (FTO).

The film thickness of the upper electrode 11 is not particularly limited, and it is preferably 0.01 μm to 100 μm, more preferably 0.01 μm to 10 μm, and particularly preferably 0.01 μm to 1 μm. It is noted that in the present invention, the thickness of each layer can be measured by observing the cross section of the photodetector element 1 using a scanning electron microscope (SEM) or the like.

Examples of the material that forms the lower electrode 12 include a metal such as platinum, gold, nickel, copper, silver, indium, ruthenium, palladium, rhodium, iridium, osmium, or aluminum, the above-described conductive metal oxide, a carbon material, and a conductive polymer. The carbon material may be any material having conductivity, and examples thereof include fullerene, a carbon nanotube, graphite, and graphene.

The lower electrode 12 is preferably a thin film of a metal or conductive metal oxide (including a thin film formed by vapor deposition), or a glass substrate or plastic substrate having this thin film. The glass substrate or the plastic substrate is preferably glass having a thin film of gold or platinum, or glass on which platinum is vapor-deposited. The film thickness of the lower electrode 12 is not particularly limited, and it is preferably 0.01 μm to 100 μm, more preferably 0.01 μm to 10 μm, and particularly preferably 0.01 μm to 1 μm.

Although not illustrated in the drawing, a transparent substrate may be arranged on the surface of the upper electrode 11 on the light incident side (the surface opposite to the side of the photoelectric conversion layer 13). Examples of the kind of transparent substrate include a glass substrate, a resin substrate, and a ceramic substrate.

In addition, although not illustrated in the drawing, an interlayer may be provided between the photoelectric conversion layer 13 and the lower electrode 12 and/or between the photoelectric conversion layer 13 and the upper electrode 11. Examples of the interlayer include a blocking layer, an electron transport layer, and a hole transport layer. Examples of the preferred aspect thereof include an aspect in which the hole transport layer is provided at any one of a gap between the photoelectric conversion layer 13 and the lower electrode 12 or a gap between the photoelectric conversion layer 13 and the upper electrode 11. It is more preferable that the electron transport layer is provided at any one of a gap between the photoelectric conversion layer 13 and the lower electrode 12 or a gap between the photoelectric conversion layer 13 and the upper electrode 11, and the hole transport layer is provided at the other gap. The hole transport layer and the electron transport layer may be a single-layer film or a laminated film having two or more layers.

The blocking layer is a layer having a function of preventing a reverse current. The blocking layer is also called a short circuit prevention layer. Examples of the material that forms the blocking layer include silicon oxide, magnesium oxide, aluminum oxide, calcium carbonate, cesium carbonate, polyvinyl alcohol, polyurethane, titanium oxide, tin oxide, zinc oxide, niobium oxide, and tungsten oxide. The blocking layer may be a single-layer film or a laminated film having two or more layers.

The electron transport layer is a layer having a function of transporting electrons generated in the photoelectric conversion layer 13 to the upper electrode 11 or the lower electrode 12. The electron transport layer is also called a hole block layer. The electron transport layer is formed of an electron transport material capable of exhibiting this function. Examples of the electron transport material include a fullerene compound such as [6,6]-phenyl-C61-butyric acid methyl ester (PC₆₁BM), a perylene compound such as perylenetetracarboxylic diimide, tetracyanoquinodimethane, titanium oxide, tin oxide, zinc oxide, indium oxide, indium tungsten oxide, indium zinc oxide, indium tin oxide, and fluorine-doped tin oxide. The electron transport layer may be a single-layer film or a laminated film having two or more layers.

The hole transport layer is a layer having a function of transporting holes generated in the photoelectric conversion layer 13 to the upper electrode 11 or the lower electrode 12. The hole transport layer is also called an electron block layer. The hole transport layer is formed of a hole transport material capable of exhibiting this function. Examples of the hole transport material include PEDOT:PSS (poly(3,4-ethylenedioxythiophene):poly(4-styrenesulfonic acid)) and MoO₃. In addition, the organic hole transport material disclosed in paragraph Nos. 0209 to 0212 of JP2001-291534A can also be used. In addition, a semiconductor quantum dot can also be used as the hole transport material. Examples of the semiconductor quantum dot material that constitutes the semiconductor quantum dot include a nano particle (a particle having a size of 0.5 nm or more and less than 100 nm) of a general semiconductor crystal [a) a Group IV semiconductor, b) a compound semiconductor of a Group IV to IV element, a Group III to V element, or a Group II to VI element, or c) a compound semiconductor consisting of a combination of three or more of a Group II element, a Group III element, a Group IV element, a Group V element, and a Group VI element].

Specific examples thereof include semiconductor materials having a relatively narrow band gap, such as PbS, PbSe, PbSeS, InN, InAs, Ge, InAs, InGaAs, CuInS, CuInSe, CuInGaSe, InSb, HgTe, HgCdTe, Ag₂S, Ag₂Se, Ag₂Te, SnS, SnSe, SnTe, Si, and InP. A ligand may be coordinated on the surface of the semiconductor quantum dot.

<Image Sensor>

The photoelectric conversion device according to the embodiment of the present invention includes the above-described photoelectric conversion element according to the embodiment of the present invention. Since the photoelectric conversion element according to the embodiment of the present invention also has excellent sensitivity to light having a wavelength in the infrared region, it can be particularly preferably used as an infrared image sensor.

The configuration of the image sensor is not particularly limited as long as it has the photoelectric conversion element according to the embodiment of the present invention and it is a configuration that functions as an image sensor.

The image sensor invention may include an infrared transmission filter layer. The infrared transmission filter layer preferably has a low light transmittance in the wavelength range of the visible region, more preferably has an average light transmittance of 10% or less, still more preferably 7.5% or less, and particularly preferably 5% or less in a wavelength range of 400 nm to 650 nm.

Examples of the infrared transmission filter layer include those composed of a resin film containing a coloring material. Examples of the coloring material include a chromatic coloring material such as a red coloring material, a green coloring material, a blue coloring material, a yellow coloring material, a purple coloring material, and an orange coloring material, and a black coloring material. It is preferable that the coloring material contained in the infrared transmission filter layer forms a black color with a combination of two or more kinds of chromatic coloring materials or a coloring material containing a black coloring material. Examples of the combination of the chromatic coloring material in a case of forming a black color by a combination of two or more kinds of chromatic coloring materials include the following aspects (C1) to (C7).

(C1) an aspect containing a red coloring material and a blue coloring material.

(C2) an aspect containing a red coloring material, a blue coloring material, and a yellow coloring material.

(C3) an aspect containing a red coloring material, a blue coloring material, a yellow coloring material, and a purple coloring material.

(C4) an aspect containing a red coloring material, a blue coloring material, a yellow coloring material, a purple coloring material, and a green coloring material.

(C5) an aspect containing a red coloring material, a blue coloring material, a yellow coloring material, and a green coloring material.

(C6) an aspect containing a red coloring material, a blue coloring material, and a green coloring material.

(C7) an aspect containing a yellow coloring material and a purple coloring material.

The chromatic coloring material may be a pigment or a dye. The infrared transmission filter layer may contain a pigment and a dye. The black coloring material is preferably an organic black coloring material. Examples of the organic black coloring material include a bisbenzofuranone compound, an azomethine compound, a perylene compound, and an azo compound.

The infrared transmission filter layer may further contain an infrared absorber. In a case where the infrared absorber is contained in the infrared transmission filter layer, the wavelength of the light to be transmitted can be shifted to the longer wavelength side. Examples of the infrared absorber include a pyrrolo pyrrole compound, a cyanine compound, a squarylium compound, a phthalocyanine compound, a naphthalocyanine compound, a quaterrylene compound, a merocyanine compound, a croconium compound, an oxonol compound, an iminium compound, a dithiol compound, a triarylmethane compound, a pyrromethene compound, an azomethine compound, an anthraquinone compound, a dibenzofuranone compound, a dithiolene metal complex, a metal oxide, and a metal boride.

The spectral characteristics of the infrared transmission filter layer can be appropriately selected according to the use application of the image sensor. Examples of the filter layer include those that satisfy any one of the following spectral characteristics of (1) to (5).

(1): A filter layer in which the maximum value of the light transmittance in the film thickness direction in a wavelength range of 400 nm to 750 nm is 20% or less (preferably 15% or less and more preferably 10% or less), and the minimum value of the light transmittance in the film thickness direction in a wavelength range of 900 nm to 1,500 nm is 70% or more (preferably 75% or more and more preferably 80% or more).

(2): A filter layer in which the maximum value of the light transmittance in the film thickness direction in a wavelength range of 400 nm to 830 nm is 20% or less (preferably 15% or less and more preferably 10% or less), and the minimum value of the light transmittance in the film thickness direction in a wavelength range of 1,000 nm to 1,500 nm is 70% or more (preferably 75% or more and more preferably 80% or more).

(3): A filter layer in which the maximum value of the light transmittance in the film thickness direction in a wavelength range of 400 nm to 950 nm is 20% or less (preferably 15% or less and more preferably 10% or less), and the minimum value of the light transmittance in the film thickness direction in a wavelength range of 1,100 nm to 1,500 nm is 70% or more (preferably 75% or more and more preferably 80% or more).

(4): A filter layer in which the maximum value of the light transmittance in the film thickness direction in a wavelength range of 400 nm to 1,100 nm is 20% or less (preferably 15% or less and more preferably 10% or less), and the minimum value in a wavelength range of 1,400 nm to 1,500 nm is 70% or more (preferably 75% or more and more preferably 80% or more).

(5): A filter layer in which the maximum value of the light transmittance in the film thickness direction in a wavelength range of 400 nm to 1,300 nm is 20% or less (preferably 15% or less and more preferably 10% or less), and the minimum value in a wavelength range of 1,600 nm to 2,000 nm is 70% or more (preferably 75% or more and more preferably 80% or more).

Further, as the infrared transmission filter, the films disclosed in JP2013-077009A, JP2014-130173A, JP2014-130338A, WO2015/166779A, WO2016/178346A, WO2016/190162A, WO2018/016232A, JP2016-177079A, JP2014-130332A, and WO2016/027798A can be used. As the infrared transmission filter, two or more filters may be used in combination, or a dual bandpass filter that transmits through two or more specific wavelength regions with one filter may be used.

The image sensor according to the embodiment of the present invention may include an infrared shielding filter for the intended purpose of improving various performances such as noise reduction. Specific examples of the infrared shielding filter include the filters disclosed in WO2016/186050A, WO2016/035695A, JP6248945B, WO2019/021767A, JP2017-067963A, and JP6506529B.

The image sensor according to the embodiment of the present invention may include a dielectric multi-layer film. Examples of the dielectric multi-layer film include those in which a plurality of layers are laminated by alternately laminating a dielectric thin film having a high refractive index (a high refractive index material layer) and a dielectric thin film having a low refractive index (a low refractive index material layer). The number of laminated layers of the dielectric thin film in the dielectric multi-layer film is not particularly limited; however, it is preferably 2 to 100 layers, more preferably 4 to 60 layers, and still more preferably 6 to 40 layers. The material that is used for forming the high refractive index material layer is preferably a material having a refractive index of 1.7 to 2.5. Specific examples thereof include Sb₂O₃, Sb₂S₃, Bi₂O₃, CeO₂, CeF₃, HfO₂, La₂O₃, Nd₂O₃, Pr₆O₁₁, Sc₂O₃, SiO, Ta₂O₅, TiO₂, TlCl, Y₂O₃, ZnSe, ZnS, and ZrO₂. The material that is used for forming the low refractive index material layer is preferably a material having a refractive index of 1.2 to 1.6. Specific examples thereof include Al₂O₃, BiF₃, CaF₂, LaF₃, PbCl₂, PbF₂, LiF, MgF₂, MgO, NdF₃, SiO₂, Si₂O₃, NaF, ThO₂, ThF₄, and Na₃AlF₆. The method for forming the dielectric multi-layer film is not particularly limited; however, examples thereof include ion plating, a vacuum deposition method using an ion beam or the like, a physical vapor deposition method (a PVD method) such as sputtering, and a chemical vapor deposition method (a CVD method). The thickness of each of the high refractive index material layer and the low refractive index material layer is preferably 0.1λ to 0.5λ in a case where the wavelength of the light to be blocked is λ (nm). Specific examples of the usable dielectric multi-layer film include the films disclosed in JP2014-130344A and JP2018-010296A.

In the dielectric multi-layer film, the transmission wavelength range is preferably present in the infrared region (preferably a wavelength range having a wavelength of more than 700 nm, more preferably a wavelength range having a wavelength of more than 800 nm, and still more preferably a wavelength range having a wavelength of more than 900 nm). The maximum transmittance in the transmission wavelength range is preferably 70% or more, more preferably 80% or more, and still more preferably 90% or more. In addition, the maximum transmittance in the shielding wavelength range is preferably 20% or less, more preferably 10% or less, and still more preferably 5% or less. In addition, the average transmittance in the transmission wavelength range is preferably 60% or more, more preferably 70% or more, and still more preferably 80% or more. In addition, in a case where the wavelength at which the maximum transmittance is exhibited is denoted by a central wavelength λₜ₁, the wavelength range of the transmission wavelength range is preferably “the central wavelength λₜ₁±100 nm”, more preferably “the central wavelength λₜ₁±75 nm”, and still more preferably “the central wavelength λₜ₁±50 nm”.

The dielectric multi-layer film may have only one transmission wavelength range (preferably, a transmission wavelength range having a maximum transmittance of 90% or more) or may have a plurality of transmission wavelength ranges.

The image sensor according to the embodiment of the present invention may include a color separation filter layer. Examples of the color separation filter layer include a filter layer including colored pixels. Examples of the kind of colored pixel include a red pixel, a green pixel, a blue pixel, a yellow pixel, a cyan pixel, and a magenta pixel. The color separation filter layer may include colored pixels having two or more colors or having only one color. It can be appropriately selected according to the use application and the intended purpose. For example, the filter disclosed in WO2019/039172A can be used.

In addition, in a case where the color separation layer includes colored pixels having two or more colors, the colored pixels of the respective colors may be adjacent to each other, or a partition wall may be provided between the respective colored pixels. The material of the partition wall is not particularly limited. Examples thereof include an organic material such as a siloxane resin or a fluororesin, and an inorganic particle such as a silica particle. In addition, the partition wall may be composed of a metal such as tungsten or aluminum.

In a case where the image sensor according to the embodiment of the present invention includes an infrared transmission filter layer and a color separation layer, it is preferable that the color separation layer is provided on an optical path different from the infrared transmission filter layer. In addition, it is also preferable that the infrared transmission filter layer and the color separation layer are arranged two-dimensionally. The description that the infrared transmission filter layer and the color separation layer are two-dimensionally arranged means that at least parts of both are present on the same plane.

The image sensor according to the embodiment of the present invention may include an interlayer such as a planarizing layer, an underlying layer, or an intimate attachment layer, an anti-reflection film, and a lens. As the anti-reflection film, for example, a film prepared from the composition disclosed in WO2019/017280A can be used. As the lens, for example, the structure disclosed in WO2018/092600A can be used.

The image sensor according to the embodiment of the present invention can be preferably used as an infrared image sensor. In addition, the image sensor according to the embodiment of the present invention can be preferably used as a sensor that senses light having a wavelength of 900 nm to 2,000 nm and can be more preferably used as a sensor that senses light having a wavelength of 900 nm to 1,600 nm.

### EXAMPLES

Hereinafter, the present invention will be described more specifically with reference to Examples. Materials, amounts used, proportions, treatment details, treatment procedures, and the like shown in the following examples can be appropriately changed without departing from the gist of the present invention. Accordingly, a scope of the present invention is not limited to the following specific examples.

### Examples 1 to 13 and Comparative Example 1

22.5 mL of oleic acid, 2 mmol of lead oxide, and 19 mL of octadecene were weighed and taken in a flask and heated at 110° C. under vacuum for 90 minutes to obtain a precursor solution. Then, the temperature of the solution was adjusted to 95° C., and the system was made into a nitrogen flow state. Then 1 mmol of hexamethyldisilathiane was injected together with 5 mL of octadecene. Immediately after the injection, the flask was naturally cooled, and at the stage where the temperature reached 30° C., 12 mL of hexane was added thereto, and a solution was recovered. An excess amount of ethanol was added to the solution, centrifugation was carried out at 10,000 rpm for 10 minutes, and the precipitate was dispersed in octane, to obtain a dispersion liquid (concentration: 40 mg/mL) of PbS quantum dots, in which oleic acid was coordinated as a ligand on the surface of the PbS quantum dot. The band gap of the PbS quantum dot estimated from the absorption measurement of the dispersion liquid of the obtained PbS quantum dots was about 0.80 eV. A test specimen 1 and a test specimen 2 were prepared by the following method using the obtained dispersion liquid of PbS quantum dots.

(Preparation of Test Specimen 1)

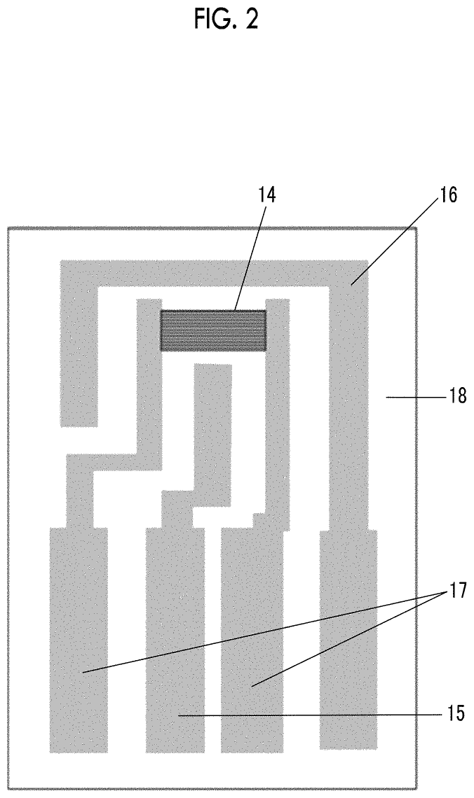

As the substrate, a substrate having 65-paired comb-shaped platinum electrodes illustrated in FIG. 2 was prepared on quartz glass. As the comb-shaped platinum electrode, a comb-shaped electrode manufactured by BAS Inc. (model number: 012126, electrode spacing: 5 μm) was used.

The dispersion liquid of PbS quantum dots was added dropwise onto the substrate, and spin coating was carried out at 2,500 rpm to form a PbS quantum dot aggregate film (a step 1). Next, a first ligand solution, which is a methanol solution of a specific ligand 1 (concentration: 25 mmol/L) described in the table below, and a second ligand solution, which is a methanol solution of a specific ligand 2 (concentration: 0.01 v/v %), were added dropwise onto the PbS quantum dot aggregate film, and then the film was allowed to stand for 10 seconds and spin-dried at 2,500 rpm for 10 seconds. Next, methanol was added as the rinsing liquid dropwise onto the PbS quantum dot aggregate film, and spin drying was carried at 2,500 rpm for 20 seconds to carry out the ligand exchange of the ligand coordinated to the PbS quantum dot from oleic acid to the specific ligand 1 and the specific ligand 2 (a step 2). The operation of the step 1 and step 2 as one cycle was repeated for 10 cycles, and a semiconductor film, which is the PbS quantum dot aggregate film in which the ligand had been subjected to ligand exchange from oleic acid to the specific ligand 1 and the specific ligand 2, was formed to a thickness of 180 nm, whereby the test specimen 1 was prepared. The thickness of the PbS quantum dot aggregate film formed per cycle was about 18 nm.

(Preparation of Test Specimen 2)

A titanium oxide film of 50 nm was formed by sputtering on a quartz glass substrate attached with a fluorine-doped tin oxide film of one inch (25.4 mm). Next, the dispersion liquid of PbS quantum dots was added dropwise onto the titanium oxide film formed on the substrate, and spin coating was carried out at 2,500 rpm to form a PbS quantum dot aggregate film (a step 1). Next, the first ligand solution, which is a methanol solution of the specific ligand 1 (concentration: 25 mmol/L) described in the table below, and the second ligand solution, which is a methanol solution of the specific ligand 2 (concentration: 0.01 v/v %), were added dropwise onto the PbS quantum dot aggregate film, and then the film was allowed to stand for 10 seconds and spin-dried at 2,500 rpm for 10 seconds. Next, methanol was added as the rinsing liquid dropwise onto the PbS quantum dot aggregate film, and spin drying was carried at 2,500 rpm for 20 seconds to carry out the ligand exchange of the ligand coordinated to the PbS quantum dot from oleic acid to the specific ligand 1 and the specific ligand 2 (a step 2). The operation of the step 1 and step 2 as one cycle was repeated for 10 cycles, and a photoelectric conversion layer, which is the PbS quantum dot aggregate film in which the ligand had been subjected to ligand exchange from oleic acid to the specific ligand 1 and the specific ligand 2, was formed to a thickness of 180 nm. The thickness of the PbS quantum dot aggregate film formed per cycle was about 18 nm.

Next, 50 nm of molybdenum oxide and 100 nm of gold were continuously vapor-deposited on the photoelectric conversion layer by vapor deposition through a metal mask in which three patterns of openings having an area of 0.16 cm² to form three element parts, whereby the test specimen 2, which is a photodiode-type photodetector element, was prepared.

(Electrical Conductivity and Photocurrent Value)

Regarding the prepared test specimen 1, the electrical conductivity and the photocurrent value of the semiconductor film were measured using a semiconductor parameter analyzer (C4156, manufactured by Agilent Technologies, Inc.).

That is, regarding the electrical conductivity, the electrical conductivity of the semiconductor film was measured by applying +5 V to the electrode in a state where the test specimen 1 was not irradiated with light and by acquiring a current value. Regarding the photocurrent value, the photocurrent value was measured in a state where the test specimen 1 was irradiated with monochrome light having a wavelength of 1,550 nm (irradiance intensity: 40 μW/cm²). A monochrome light source system MLS-1510 (manufactured by Asahi Spectra Co., Ltd.) was used for light irradiation.

(External Quantum Efficiency and In-Plane Uniformity)

The external quantum efficiency and the in-plane uniformity were evaluated using the prepared test specimen 2.

That is, the external quantum efficiency (EQE) was measured when the test specimen 2 was irradiated with monochrome light (irradiation intensity: 40 μW/cm²) having a wavelength of 1,550 nm in a state where a reverse voltage of 2 V was applied thereto. Regarding the external quantum efficiency (EQE), the number of electrons generated by light irradiation was calculated by subtracting the current value in a state of not being irradiated with light from the current value in a state of being irradiated with light. The value of external quantum efficiency (EQE) was obtained by dividing the number of electrons generated by light irradiation by the number of photons of the light with which irradiation was carried out. The average value of the three element parts of the test specimen 2 was taken as the value of the external quantum efficiency (EQE) in the table was.

In addition, regarding in-plane uniformity, the external quantum efficiency of each of the three element parts of the test specimen 2 was measured, and the difference between the value of the highest external quantum efficiency and the value of the lowest external quantum efficiency was calculated as ΔEQE (=the value of the highest external quantum efficiency−the value of the lowest external quantum efficiency), and the in-plane uniformity (the in-plane uniformity of the external quantum efficiency) was evaluated. It means that the smaller the value of ΔEQE, the better the in-plane uniformity.

TABLE 1

| | | | | | External | |
|---|---|---|---|---|---|---|
| | | | Electrical | Photocurrent | quantum | In-plane |
| | | | conductivity | value | efficiency | uniformity |
| | Specific ligand 1 | Specific ligand 2 | (S/m) | (A) | (EQE (%)) | (ΔEQE (%)) |
| Example 1 | InCl₃ | Thioglycolic acid | 1.1 × 10⁻² | 2.5 × 10⁻⁵ | 42.1 | 2.2 |
| Example 2 | InBr₃ | Thioglycolic acid | 1.0 × 10⁻² | 2.7 × 10⁻⁵ | 43.2 | 2.3 |
| Example 3 | ZnI₂ | Thioglycolic acid | 1.1 × 10⁻² | 3.5 × 10⁻⁵ | 47.8 | 2.5 |
| Example 4 | ZnBr₂ | Thioglycolic acid | 1.2 × 10⁻² | 3.3 × 10⁻⁵ | 46.5 | 2.4 |
| Example 5 | ZnCl₂ | Thioglycolic acid | 1.3 × 10⁻² | 3.2 × 10⁻⁵ | 45.2 | 2.1 |
| Example 6 | CdCl₂ | Thioglycolic acid | 1.2 × 10⁻² | 3.0 × 10⁻⁵ | 46.3 | 2.3 |
| Example 7 | ZnI₂ | 2-aminoethanol | 7.5 × 10⁻³ | 2.0 × 10⁻⁵ | 41.2 | 2.5 |
| Example 8 | ZnI₂ | 2-aminoethanethiol | 1.1 × 10⁻² | 2.2 × 10⁻⁵ | 43.5 | 2.8 |
| Example 9 | ZnI₂ | 2-aminomercaptoethanol | 8.5 × 10⁻³ | 1.9 × 10⁻⁵ | 44.8 | 2.2 |
| Example 10 | ZnI₂ | Glycolic acid | 6.6 × 10⁻³ | 1.4 × 10⁻⁵ | 42.5 | 2.6 |
| Example 11 | ZnI₂ | Diethylenetriamine | 6.0 × 10⁻³ | 1.2 × 10⁻⁵ | 41.6 | 2.7 |
| Example 12 | ZnI₂ | Tris(2-aminoethyl)amine | 5.0 × 10⁻³ | 1.1 × 10⁻⁵ | 40.8 | 2.6 |
| Example 13 | ZnI₂ | (Aminomethyl)phosphonic | 6.3 × 10⁻³ | 1.5 × 10⁻⁵ | 41.2 | 2.4 |
| | | acid | | | | |
| Example 14 | ZnI₂ + CdCl₂ | Thioglycolic acid | 1.1 × 10⁻² | 3.1 × 10⁻⁵ | 46.5 | 2.5 |
| Example 15 | ZnI₂ | Thioglycolic acid + | 8.5 × 10⁻³ | 2.1 × 10⁻⁵ | 43.8 | 2.4 |
| | | 2-aminoethanol | | | | |
| Example 16 | ZnI₂ | Thioglycolic acid + | 7.6 × 10⁻³ | 2.3 × 10⁻⁵ | 40.4 | 3.1 |
| | | 3-mercaptopropionic acid | | | | |
| Comparative | ZnI₂ | 3-mercaptopropionic acid | 3.3 × 10⁻³ | 7.2 × 10⁻⁶ | 37.9 | 5.1 |
| Example 1 | | | | | | |
| Comparative | ZnI₂ | — | 1.6 × 10⁻³ | 4.8 × 10⁻⁶ | 25.6 | 2.6 |
| Example 2 | | | | | | |
| Comparative | — | Thioglycolic acid | 6.6 × 10⁻³ | 1.6 × 10⁻⁵ | 21.1 | 2.5 |
| Example 3 | | | | | | |

The ligand described in the column of specific ligand 1 in the above table corresponds to the first ligand in the present invention. In addition, among the ligands described in the column of the specific ligand 2, thioglycolic acid, 2-aminoethanol, 2-aminoethanethiol, 2-mercaptoethanol, diethylenetriamine, tris(2-aminoethyl)amine, and (aminomethyl)phosphonic acid correspond to the second ligand in the present invention.

In addition, in Example 14, a methanol solution in which ZnI₂ was mixed at a concentration of 12.5 mmol/L and CdCl₂ was mixed at a concentration of 12.5 mmol/L was used as the first ligand solution. In addition, in Example 15, a methanol solution in which thioglycolic acid was mixed at a concentration of 0.005 v/v % and 2-aminoethanol was mixed at a concentration of 0.005 v/v % was used as the second ligand solution. In addition, in Example 16, a second ligand solution in which thioglycolic acid was mixed at a concentration of 0.008 v/v % and 3-mercaptopropionic acid was mixed at a concentration of 0.002 v/v % was used. In addition, in Comparative Example 2, the ligand exchange was carried out using only the first ligand solution. In addition, in Comparative Example 3, the ligand exchange was carried out using only the second ligand solution.

As shown in the above table, in Examples the electrical conductivity, the photocurrent value, and the external quantum efficiency high, and the in-plane uniformity was excellent in Examples.

On the other hand, the in-plane uniformity was inferior in Comparative Example 1, which is an example in which 3-mercaptopropionic acid was used instead of the second ligand. In addition, in Comparative Example 2 in which only the first ligand according to the embodiment of the present invention is contained as a ligand, it was presumed that the shortening of the distance between the semiconductor quantum dots was insufficient, and the photocurrent value and the external quantum efficiency were low. In addition, the external quantum efficiency was low in Comparative Example 3 which contains only the first ligand according to the embodiment of the present invention as a ligand. This is presumed to be because there are many surface defects of the semiconductor dot.

### Example 17

The test specimen 1 and the test specimen 2 were prepared in the same manner as in Example 3 except that the kind of the rinsing liquid used in the step 2 was changed from methanol to acetonitrile in the preparation of the test specimen 1 and the test specimen 2. As a result of evaluating the electrical conductivity, the photocurrent value, the external quantum efficiency, and the in-plane uniformity using the obtained test specimens 1 and 2 by the same method as above, the electrical conductivity was 1.4×10⁻² S/m, the photocurrent value was 4.8×10⁻⁵ A, the external quantum efficiency (EQE) was 49.5%, and the in-plane uniformity (ΔEQE) was 1.4%. All of the electrical conductivity, the photocurrent value, the external quantum efficiency, and the in-plane uniformity thereof were improved as compared with Example 3.

### Examples 18 and 19

A dispersion liquid having a concentration of 80 mg/mL was used as the dispersion liquid of PbS quantum dots, a methanol solution of the specific ligand 1 (ZnI₂) (concentration: 25 mmol/L) shown in the table below was used as the first ligand solution, a methanol solution of the specific ligand 2 (2-mercaptoethanol (Example 18) or thioglycolic acid (Example 19)) (concentration: 0.01 v/v %) shown in the table below was used as the second ligand solution, the operation of the step 1 and step 2 as one cycle was repeated for 5 cycles in the same manner as described above, and a semiconductor film, which is the PbS quantum dot aggregate film in which the ligand had been subjected to ligand exchange from oleic acid to the specific ligand 1 and the specific ligand 2, was formed to a thickness of about 180 nm, whereby the test specimen 1 and the test specimen 2 were prepared. The thickness of the PbS quantum dot aggregate film formed per cycle was about 37 nm. The electrical conductivity, the photocurrent value, the external quantum efficiency, and the in-plane uniformity were evaluated using the obtained test specimens 1 and 2 by the same method as above.

The complex stability constant K1 of thioglycolic acid with respect to the Pb atom was 8.5, and the complex stability constant K1 of 2-mercaptoethanol with respect to the Pb atom was 6.7. The values of these complex stability constants K1 were obtained using Sc-Databese ver. 5.85 (Academic Software) (2010).

TABLE 2

| | | | | | External | |
|---|---|---|---|---|---|---|
| | | | Electrical | Photocurrent | quantum | In-plane |
| | | | conductivity | value | efficiency | uniformity |
| | Specific ligand 1 | Specific ligand 2 | (S/m) | (A) | (EQE (%)) | (ΔEQE (%)) |
| Example 18 | ZnI₂ | 2-aminomercaptoethanol | 7.5 × 10⁻³ | 1.6 × 10⁻⁵ | 41.8 | 2.6 |
| Example 19 | ZnI₂ | Thioglycolic acid | 1.0 × 10⁻² | 3.3 × 10⁻⁵ | 45.8 | 3.1 |

Even in a case where the thickness of the PbS quantum dot aggregate film formed per cycle was increased, an excellent electrical conductivity, an excellent photocurrent value, an excellent external quantum efficiency, and an excellent in-plane uniformity were exhibited. In addition, as shown in the above table, in Example 19 in which thioglycolic acid (the complex stability constant K1 with respect to Pb is 8.5) was used, an excellent electrical conductivity, an excellent photocurrent value, an excellent external quantum efficiency, and an excellent in-plane uniformity were exhibited as compared with Example 18 in which 2-mercaptoethanol (the complex stability constant K1 with respect to Pb is 6.7).

### Example 20

The test specimens 1 and 2 were prepared in the same manner as in Example 1 except that in the step 2, a methanol solution containing 0.01 v/v % of thioglycolic acid and 25 mmol/L of ZnI₂ was added as the ligand solution dropwise onto the PbS quantum dot aggregate film. As a result of evaluating the electrical conductivity, the photocurrent value, the external quantum efficiency, and the in-plane uniformity using the obtained test specimens 1 and 2, the performance was the same as that of Example 1.

In a case where an image sensor is prepared by a known method by using the photodetector element obtained in Example described and incorporating it into a solid-state imaging element together with an optical filter prepared according to the methods disclosed in WO2016/186050A and WO2016/190162A, it is possible to obtain an image sensor having good visible and infrared imaging performance.

In each embodiment, the same effect can be obtained even in a case where the semiconductor quantum dots of the photoelectric conversion layer are changed to PbSe quantum dots.

### EXPLANATION OF REFERENCES

1: photodetector element
11: upper electrode
12: lower electrode
13: photoelectric conversion layer
14: 65-paired comb-shaped electrode
15: reference electrode
16: counter electrode
17: working electrode
18: quartz glass

What is claimed is:

1. A semiconductor film comprising:
aggregates of semiconductor quantum dots containing a metal atom; and
a ligand that is coordinated to the semiconductor quantum dot,
wherein the ligand contains a first ligand that is an inorganic halide and a second ligand that is represented by any one of Formulae (A) to (C); 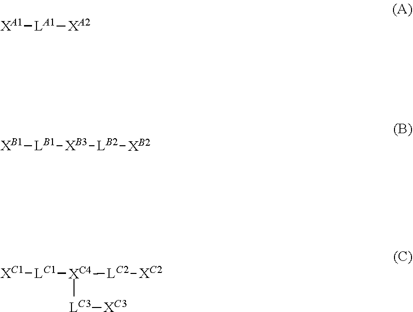
in Formula (A), X^{A1} and X^{A2} each independently represent a thiol group, an amino group, a hydroxy group, a carboxy group, a sulfo group, a phospho group, or a phosphonic acid group,
L^{A1} represents a hydrocarbon group, X^{A1} and X^{A2} are separated by L^{A1} by 1 or 2 atoms, and
in a case where one of X^{A1} and X^{A2} is a thiol group and the other is a carboxy group, X^{A1} and X^{A2} are separated by L^{A1} by 1 atom;
in Formula (B), X^{B1} and X^{B2} each independently represent a thiol group, an amino group, a hydroxy group, a carboxy group, a sulfo group, a phospho group, or a phosphonic acid group,
X^{B3} represents S, O, or NH,
L^{B1} and L^{B2} each independently represent a hydrocarbon group,
X^{B1} and X^{B3} are separated by L^{B1} by 1 or 2 atoms, and
X^{B2} and X^{B3} are separated by L^{B2} by 1 or 2 atoms;
in Formula (C), X^{C1} to X^{C3} each independently represent a thiol group, an amino group, a hydroxy group, a carboxy group, a sulfo group, a phospho group, or a phosphonic acid group,
X^{C4} represents N,
L^{C1} to L^{C3} each independently represent a hydrocarbon group,
X^{C1} and X^{C4} are separated by L^{C1} by 1 or 2 atoms,
X^{C2} and X^{C4} are separated by L^{C2} by 1 or 2 atoms, and
X^{C3} and X^{C4} are separated by L^{C3} by 1 or 2 atoms.

2. The semiconductor film according to claim 1,
wherein the semiconductor quantum dot contains a Pb atom.

3. The semiconductor film according to claim 1,
wherein the first ligand contains at least one selected from a Group 12 element or a Group 13 element.

4. The semiconductor film according to claim 1,
wherein the first ligand contains a Zn atom.

5. The semiconductor film according to claim 1,
wherein the first ligand contains an iodine atom.

6. The semiconductor film according to claim 1,
wherein the second ligand is at least one selected from thioglycolic acid, 2-aminoethanol, 2-aminoethanethiol, 2-mercaptoethanol, diethylenetriamine, tris(2-aminoethyl)amine, (aminomethyl)phosphonic acid, or derivatives thereof.

7. The semiconductor film according to claim 1,
wherein the semiconductor film contains two or more kinds of the first ligand.

8. The semiconductor film according to claim 1,
wherein the semiconductor film contains two or more kinds of the second ligand.

9. The semiconductor film according to claim 1,
wherein the semiconductor film further contains a ligand other than the first ligand and the second ligand.

10. A photoelectric conversion element comprising the semiconductor film according to claim 1.

11. The photoelectric conversion element according to claim 10,
wherein the photoelectric conversion element is a photodiode-type photodetector element.

12. An image sensor comprising the photoelectric conversion element according to claim 10.

13. The image sensor according to claim 12,
wherein the image sensor senses light having a wavelength of 900 nm to 1,600 nm.

14. A manufacturing method for a semiconductor film, comprising:
a semiconductor quantum dot aggregate forming step of applying a semiconductor quantum dot dispersion liquid containing semiconductor quantum dots that contain a metal atom, a third ligand that is coordinated to a semiconductor quantum dot and that is different from a first ligand which is an inorganic halide and a second ligand which is represented by any one of Formulae (A) to (C), and a solvent, onto a substrate to form a film of aggregates of the semiconductor quantum dots; and
a ligand exchange step of applying a ligand solution 1 containing the first ligand which is an inorganic halide and a solvent, and a ligand solution 2 containing the second ligand which is represented by any one of Formulae (A) to (C), and a solvent, or applying a ligand solution 3 containing the first ligand which is an inorganic halide, the second ligand which is represented by any one of Formulae (A) to (C), and a solvent, onto the film of the aggregates of the semiconductor quantum dots formed by the semiconductor quantum dot aggregate forming step, to exchange the third ligand coordinated to the semiconductor quantum dot with the first ligand and the second ligand; 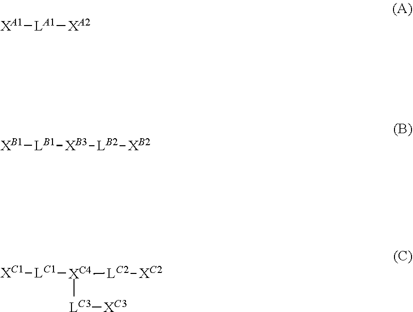
in Formula (A), X^{A1} and X^{A2} each independently represent a thiol group, an amino group, a hydroxy group, a carboxy group, a sulfo group, a phospho group, or a phosphonic acid group,
L^{A1} represents a hydrocarbon group, X^{A1} and X^{A2} are separated by L^{A1} by 1 or 2 atoms, and
in a case where one of X^{A1} and X^{A2} is a thiol group and the other is a carboxy group, X^{A1} and X^{A2} are separated by L^{A1} by 1 atom;
in Formula (B), X^{B1} and X^{B2} each independently represent a thiol group, an amino group, a hydroxy group, a carboxy group, a sulfo group, a phospho group, or a phosphonic acid group,
X^{B3} represents S, O, or NH,
L^{B1} and L^{B2} each independently represent a hydrocarbon group,
X^{B1} and X^{B3} are separated by L^{B1} by 1 or 2 atoms, and
X^{B2} and X^{B3} are separated by L^{B2} by 1 or 2 atoms;
in Formula (C), X^{C1} to X^{C3} each independently represent a thiol group, an amino group, a hydroxy group, a carboxy group, a sulfo group, a phospho group, or a phosphonic acid group,
X^{C4} represents N,
L^{C1} to L^{C3} each independently represent a hydrocarbon group,
X^{C1} and X^{C4} are separated by L^{C1} by 1 or 2 atoms,
X^{C2} and X^{C4} are separated by L^{C2} by 1 or 2 atoms, and
X^{C3} and X^{C4} are separated by L^{C3} by 1 or 2 atoms.

15. The manufacturing method for a semiconductor film according to claim 14, further comprising a rinsing step of carrying out rinsing by bringing an aprotic solvent into contact with the film of the aggregates of the semiconductor quantum dots.

16. The manufacturing method for a semiconductor film according to claim 15,
wherein the aprotic solvent is an aprotic polar solvent.

17. The manufacturing method for a semiconductor film according to claim 15,
wherein the aprotic solvent is at least one selected from acetonitrile or acetone.

18. The manufacturing method for a semiconductor film according to claim 14,
wherein in the semiconductor quantum dot aggregate forming step, a film of the aggregates of the semiconductor quantum dots having a thickness of 30 nm or more is formed, and
a complex stability constant K1 of the second ligand with respect to the metal atom contained in the semiconductor quantum dot is 6 or more.

19. The manufacturing method for a semiconductor film according to claim 18,
wherein the complex stability constant K1 of the second ligand with respect to the metal atom contained in the semiconductor quantum dot is 8 or more.

20. The manufacturing method for a semiconductor film according to claim 18,
wherein the semiconductor quantum dot contains a Pb atom, and
the complex stability constant K1 of the second ligand with respect to the Pb atom is 6 or more.
